(19) United States
(12) Patent Application Publication
(10) Pub. No.: US 2025/0266806 A1
(43) Pub. Date: Aug. 21, 2025

(54) Bulk Acoustic Wave Resonator and Manufacturing method Thereof

(71) Applicant: Wuhan MEMSonics Technologies Co.,Ltd., Wuhan (CN)

(72) Inventors: Bowoon SOON, Wuhan (CN); Xin TONG, Wuhan (CN); Jie ZHOU, Wuhan (CN)

(73) Assignee: Wuhan MEMSonics Technologies Co.,Ltd., Wuhan (CN)

(21) Appl. No.: 18/932,281

(22) Filed: Oct. 30, 2024

(30) Foreign Application Priority Data
Feb. 21, 2024 (CN) 202410194898.4

(51) Int. Cl. H03H 9/17; H03H 3/02

(52) U.S. Cl. CPC H03H 9/173; H03H 3/02; H03H 2003/021

(57) ABSTRACT

The present disclosure provides a bulk acoustic wave resonator and a manufacturing method thereof, and relates to the technical field of resonators. The bulk acoustic wave resonator includes a substrate, and a lower conductive layer, a piezoelectric layer and an upper conductive layer, which are sequentially disposed on the substrate in a stacked manner, wherein the lower conductive layer, the piezoelectric layer and the upper conductive layer have an overlapping region in a stacking direction, a first cavity located between the upper conductive layer and the piezoelectric layer is disposed outside the overlapping region, a plurality of first support columns are disposed inside the first cavity, the plurality of first support columns are supported between the piezoelectric layer and the upper conductive layer, the plurality of first support columns divide the first cavity into a plurality of through holes.

### TECHNICAL FIELD

The present disclosure relates to the technical field of resonators, and in particular to a bulk acoustic wave resonator and a manufacturing method thereof.

### BACKGROUND

At present, with the rapid development of wireless communications, more and more devices transmit and receive information at higher frequency bands, therefore the requirements for radio frequency front-end circuits are increasingly harsh, and the market demands for high-performance filters are increasingly great. Bulk acoustic wave filters are gradually becoming a mainstream in the market due to the characteristics of high quality factors, good out-of-band rejection, high rectangle coefficients, and the like.

The bulk acoustic wave filter is mainly formed by cascading bulk acoustic wave resonators by a specific circuit. After alternating current is applied to an electrode of the bulk acoustic wave resonator, longitudinal vibration is mainly generated, that is, an acoustic wave propagates towards the thickness direction of a piezoelectric layer. However, due to an acoustic impedance mismatch between the electrode and the piezoelectric layer and the non-uniformity of an electric field, other lateral mode acoustic waves may be excited at the same time, resulting in energy leakage. In addition, heat is generated inside of the resonator, which greatly affects the reliability of a device.

### SUMMARY

One aspect of the embodiments of the present disclosure provides a bulk acoustic wave resonator, including a substrate, and a lower conductive layer, a piezoelectric layer and an upper conductive layer, which are sequentially disposed on the substrate in a stacked manner, wherein the lower conductive layer, the piezoelectric layer and the upper conductive layer have an overlapping region in a stacking direction, a first cavity located between the upper conductive layer and the piezoelectric layer is disposed outside the overlapping region, a plurality of first support columns are disposed in the first cavity, the plurality of first support columns are supported between the piezoelectric layer and the upper conductive layer, the plurality of first support columns divide the first cavity into a plurality of through holes, and the plurality of through holes are distributed in a direction from a center of the overlapping region to a boundary of the overlapping region.

Optionally, wherein a second cavity is disposed between the substrate and the lower conductive layer; and
orthographic projections of a part of through holes close to the center of the overlapping region among the plurality of through holes in the stacking direction are located in the second cavity; and/or, orthographic projections of a part of through holes away from the center of the overlapping region among the plurality of through holes in the stacking direction do not overlap with an orthographic projection of the second cavity in the stacking direction.

Optionally, a spacing between two adjacent first support columns is a first spacing, and at least part of the first spacings are different from each other.

Optionally, a plurality of the first cavities are disposed outside the overlapping region, and the plurality of the first cavities are distributed at intervals along a periphery of the overlapping region.

Optionally, among the plurality of first cavities, a number of through holes contained in at least two first cavities is different.

Optionally, the upper conductive layer is provided with an anchoring portion, the anchoring portion is located above the first cavity, and a surface of a side of the anchoring portion that faces away from the piezoelectric layer is an undulating surface.

Optionally, the upper conductive layer includes an upper electrode located in the overlapping region, and an upper electrode lead-out portion located outside the overlapping region, a periphery of the upper electrode is composed of a first edge and a second edge, the upper electrode is connected with the upper electrode lead-out portion by the first edge, a third cavity is disposed between the upper electrode and the piezoelectric layer, the third cavity is located on the second edge, and the first cavity is located on the first edge.

Optionally, a side of the third cavity that faces away from the center of the overlapping region is closed by a second support column supported between the upper electrode and the piezoelectric layer.

Optionally, a plurality of third cavities are disposed between the upper electrode and the piezoelectric layer, and the plurality of third cavities are distributed at intervals along the second edge.

Optionally, when the second cavity is disposed between the substrate and the lower conductive layer, an orthographic projection of the third cavity in the stacking direction does not overlap with an orthographic projection of the second cavity in the stacking direction.

Optionally, a fourth cavity located outside the overlapping region is disposed in the lower conductive layer, the fourth cavity penetrates through the lower conductive layer, a plurality of third support columns supported between the piezoelectric layer and the substrate are disposed in the fourth cavity, the plurality of third support columns divide the fourth cavity into a plurality of compartments, and the plurality of compartments are distributed in the direction from the center of the overlapping region to the boundary of the overlapping region.

Optionally, when the second cavity is disposed between the substrate and the lower conductive layer, an orthographic projection of the fourth cavity in the stacking direction does not overlap with an orthographic projection of the second cavity in the stacking direction.

Optionally, the second cavity, the third cavity and the fourth cavity are distributed in the direction from the center of the overlapping region to the boundary of the overlapping region.

Optionally, a spacing between two adjacent third support columns is a second spacing, and at least part of the second spacings are different from each other.

Another aspect of the embodiments of the present disclosure provides a bulk acoustic wave resonator manufacturing method, including:
forming a lower conductive layer and a piezoelectric layer on a substrate;
forming, on the piezoelectric layer, a plurality of first sacrificial portions, an upper conductive layer covering the plurality of first sacrificial portions, and first support columns filled between two adjacent first sacrificial portions, wherein the lower conductive layer, the piezoelectric layer and the upper conductive layer have an overlapping region in a stacking direction, the plurality of first sacrificial portions are located outside the overlapping region, and the plurality of first sacrificial portions are distributed at intervals in a direction from a center of the overlapping region to a boundary of the overlapping region; and
releasing the plurality of first sacrificial portions to form a first cavity between the upper conductive layer and the piezoelectric layer, wherein the first cavity is divided by the plurality of first support columns into a plurality of through holes which are distributed in the direction from the center of the overlapping region to the boundary of the overlapping region.

Optionally, forming, on the piezoelectric layer, the plurality of first sacrificial portions, the upper conductive layer covering the plurality of first sacrificial portions, and the plurality of first support columns filled between two adjacent first sacrificial portions, includes:
forming a first sacrificial layer on the piezoelectric layer;
etching the first sacrificial layer to form the plurality of first sacrificial portions and a second sacrificial portion; and
forming, on the piezoelectric layer, the upper conductive layer covering the plurality of first sacrificial portions and the second sacrificial portion, and the plurality of first support columns filled between two adjacent first sacrificial portions, wherein the second sacrificial portion is released to form a third cavity located between the upper conductive layer and the piezoelectric layer, the upper conductive layer includes an upper electrode located in the overlapping region, and an upper electrode lead-out portion located outside the overlapping region, a periphery of the upper electrode is composed of a first edge and a second edge, the upper electrode is connected with the upper electrode lead-out portion by the first edge, a third cavity is located on the second edge, and the first cavity is located on the first edge.

Optionally, forming the lower conductive layer and the piezoelectric layer on the substrate includes:
forming the lower conductive layer on the substrate;
etching the lower conductive layer to form a fourth cavity penetrating through the lower conductive layer in the lower conductive layer, and a plurality of third support columns located in the fourth cavity, wherein the plurality of third support columns divide the fourth cavity into a plurality of compartments, and the plurality of compartments are distributed in the direction from the center of the overlapping region to the boundary of the overlapping region;
respectively filling the plurality of compartments with third sacrificial portions, so that a surface of a side of the lower conductive layer that faces away from the substrate is flush; and
forming the piezoelectric layer on a surface of a side of the lower conductive layer that faces away from the substrate.

Optionally, forming the lower conductive layer on the substrate includes: depositing a seed layer on the substrate, and forming the lower conductive layer on the seed layer.

Optionally, before forming the lower conductive layer on the substrate, the method further includes:
etching the substrate to form a second cavity; and
filling the second cavity with a fourth sacrificial portion, so that an upper surface of the substrate is flush.

Optionally, the method further includes:
at least etching the upper conductive layer, the piezoelectric layer and the lower conductive layer to form a release hole connected to the fourth sacrificial portion, so as to release the fourth sacrificial portion via the release hole, wherein the release hole is located on an edge of the third cavity.

### BRIEF DESCRIPTION OF THE DRAWINGS

To illustrate technical solutions of the embodiments of the present disclosure more clearly, a brief introduction on the drawings which are needed in the embodiments will be given below, it should be understood that the following drawings only illustrate some embodiments of the present disclosure, thus should not be considered as limiting the scope, and for those ordinary skilled in the art, other related drawings may be obtained according to these drawings without creative efforts.

FIG. 1 is a schematic structural diagram of a bulk acoustic wave resonator provided in an embodiment of the present disclosure;

FIG. 2 is a partial enlarged view in FIG. 1;

FIG. 3 is a top view of a bulk acoustic wave resonator provided in an embodiment of the present disclosure;

FIG. 4 is a schematic structural diagram of another bulk acoustic wave resonator provided in an embodiment of the present disclosure;

FIG. 5 is a top view of another bulk acoustic wave resonator provided in an embodiment of the present disclosure;

FIG. 6 is a schematic structural diagram of yet another bulk acoustic wave resonator provided in an embodiment of the present disclosure;

FIG. 7 is a first schematic state diagram of a bulk acoustic wave resonator manufacturing method provided in an embodiment of the present disclosure;

FIG. 8 is a second schematic state diagram of a bulk acoustic wave resonator manufacturing method provided in an embodiment of the present disclosure;

FIG. 9 is a third schematic state diagram of a bulk acoustic wave resonator manufacturing method provided in an embodiment of the present disclosure;

FIG. 10 is a fourth schematic state diagram of a bulk acoustic wave resonator manufacturing method provided in an embodiment of the present disclosure;

FIG. 11 is a first schematic state diagram of another bulk acoustic wave resonator manufacturing method provided in an embodiment of the present disclosure;

FIG. 12 is a second schematic state diagram of another bulk acoustic wave resonator manufacturing method provided in an embodiment of the present disclosure; and

FIG. 13 is a third schematic state diagram of another bulk acoustic wave resonator manufacturing method provided in an embodiment of the present disclosure.

Icons: 10—substrate; 11—second cavity; 12—lower conductive layer; 13—piezoelectric layer; 14—electrode connection end; 15—electrode connection portion; 16—release hole; 17—upper conductive layer; 17-1—anchoring portion; 17-2—upper electrode; 17-3—upper electrode lead-out portion; 18—first cavity; 18-1—through hole; 19—first acoustic reflection structure; 20—first support column; 21—third cavity; 22—second support column; 23—fourth cavity; 23-1—compartment; 24—third support column; 25—seed layer; 26—fourth sacrificial portion; 27—first sacrificial portion; 28—second sacrificial portion; 29—lower conductive layer lead-out hole; 30—third sacrificial portion.

### DETAILED DESCRIPTION OF THE EMBODIMENTS

The implementations set forth below represent information required for enabling those skilled in the art to practice the implementations, and illustrate optimal modes for practicing the implementations. After reading the following description with reference to the drawings, those skilled in the art will understand the concepts of the present disclosure and will recognize disclosures of these concepts not specifically proposed herein. It should be understood that these concepts and disclosures fall within the scope of the present disclosure and the appended claims.

It should be understood that, although the terms first, second and the like may be used herein to describe various elements, these elements should not be limited by these terms. These terms are only used to distinguish one element from another element. For embodiment, without departing from the scope of the present disclosure, a first element may be referred to as a second element, and similarly, the second element may be referred to as the first element. As used herein, the term “and/or” includes any and all combinations of one or more of associated listed items.

It should be understood that, when one element (such as a layer, a region or a substrate) is referred to as being “on another element” or “extending onto another element”, it may be directly on the other element or directly extend onto the other element, or there may also be an intervening element. On the contrary, when one element is referred to as being “directly on another element” or “directly extending onto another element”, there is no intervening element. Likewise, it should be understood that when one element (such as a layer, a region or a substrate) is referred to as being “on another element” or “extending on another element”, it may be directly on another element or directly extend on another element, or there may also an intervening element. On the contrary, when one element is referred to as being “directly on another element” or “directly extending on another element”, there is no intervening element. It should also be understood that when one element is referred to as being “connected” or “coupled” to another element, it may be directly connected or coupled to the other element, or there may be an intervening element. On the contrary, when one element is referred to as being “directly connected” or “directly coupled” to another element, there is no intervening element.

Related terms such as “below”, “above”, “upper portion”, “lower portion”, “horizontal” or “vertical” may be used herein to describe a relationship between one element, layer or region and another element, layer or region, as shown in the figures. It should be understood that these terms and those terms discussed above are intended to encompass different orientations of an apparatus in addition to the orientations depicted in the figures.

The terms used herein are for the purpose of describing particular implementations only and are not intended to limit the present disclosure. As used herein, unless the context clearly indicates otherwise, singular forms “a”, “an” and “the” are intended to include plural forms as well. It should also be understood that, when used herein, the term “include” indicates the presence of said features, integers, steps, operations, elements, and/or components, but does not preclude the presence or addition of one or more other features, integers, steps, operations, elements, components, and/or groups of the above items.

Unless otherwise defined, all terms (including technical terms and scientific terms) used herein have the same meanings as commonly understood by those ordinary skilled in the art to which the present disclosure belongs. It should also be understood that the terms used herein should be interpreted as having meanings consistent with the meanings thereof in the present specification and related arts, and cannot be interpreted in an idealized or overly formal sense unless expressly so defined herein.

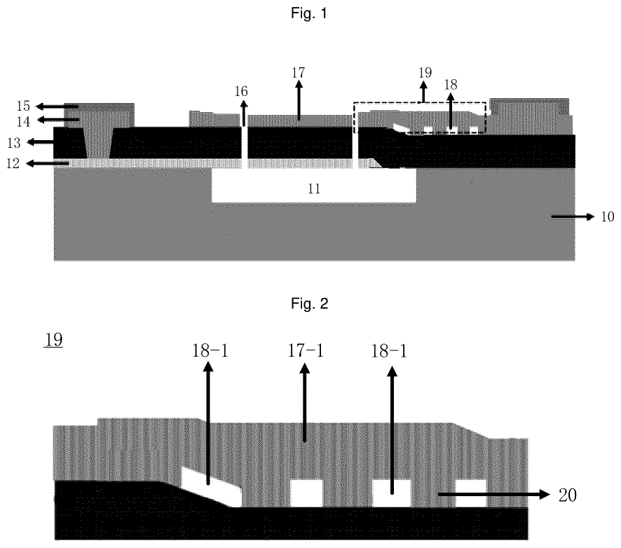

One aspect of the embodiments of the present disclosure provides a bulk acoustic wave resonator, as shown in FIG. 1, the bulk acoustic wave resonator includes a substrate 10, a lower conductive layer 12, a piezoelectric layer 13 and an upper conductive layer 17, wherein the lower conductive layer 12, the piezoelectric layer 13 and the upper conductive layer 17 are sequentially disposed on the substrate 10 in a stacked manner. The lower conductive layer 12, the piezoelectric layer 13 and the upper conductive layer 17 constitute a piezoelectric stack structure of the bulk acoustic wave resonator. After a voltage is applied to the upper conductive layer 17 and the lower conductive layer 12, the piezoelectric layer 13 generates an inverse piezoelectric effect, thereby realizing the conversion of electric energy and mechanical energy.

In order to better understand the present disclosure conveniently, it is defined that the lower conductive layer 12, the piezoelectric layer 13 and the upper conductive layer 17 have an overlapping region in a stacking direction. Generally, the overlapping region is used as an effective resonant region in the art. Of course, in embodiments in which there is a second cavity 11 located between the substrate 10 and the lower conductive layer 12, an overlapping portion between the overlapping region and the second cavity 11 is also often used as the effective resonance region, which is not specifically limited in the present disclosure.

When the piezoelectric layer 13 generates the inverse piezoelectric effect, acoustic waves in a lateral mode are inevitably generated. In order to alleviate this adverse phenomenon, in the present disclosure, an acoustic reflection structure for reflecting laterally leaked acoustic waves is formed at a position of the piezoelectric stack structure, which is located on the boundary of the overlapping region, so as to improve a quality factor of the bulk acoustic wave resonator by the acoustic reflection structure, and to optimize the heat dissipation capability of the bulk acoustic wave resonator and a filter formed by the bulk acoustic wave resonator.

The specific arrangement position and specific composition of the foregoing acoustic reflection structure have various embodiments, and for ease of understanding, some embodiments are described below in combination with the drawings.

### Embodiment 1

Referring to FIG. 1, the acoustic reflection structure includes a first acoustic reflection structure 19, and the first acoustic reflection structure 19 is located on the boundary of the overlapping region. Specifically, the first acoustic reflection structure 19 is that: a first cavity 18 is disclosed between the upper conductive layer 17 and the piezoelectric layer 13, and the first cavity 18 is located outside the overlapping region, so that an orthographic projection of the first cavity 18 does not overlap with an orthographic projection of the lower conductive layer 12 in the stacking direction. With reference to FIG. 2, a plurality of first support columns 20 are disposed in the first cavity 18, the plurality of first support columns 20 divide the first cavity 18 into a plurality of through holes 18-1, and the plurality of through holes 18-1 are distributed in a direction from a center of the overlapping region to a boundary of the overlapping region.

In this way, by an impedance mismatch formed by the plurality of through holes 18-1 with the plurality of first support columns 20 and the upper conductive layer 17, the first acoustic reflection structure 19 has a continuous acoustic reflection capability. The first acoustic reflection structure 19 can reflect the lateral acoustic waves for multiple times, thereby facilitating a reduction in an anchor loss, thus improving the quality factor.

Since the first support column 20 is supported between the piezoelectric layer 13 and the upper conductive layer 17, the first support column 20 is used for lifting the upper conductive layer 17 at the first acoustic reflection structure 19 away from the piezoelectric layer 13, thereby enhancing the heat dissipation capability of the resonator. In addition, the upper conductive layer 17 is better supported through the first support column 20, therefore the first acoustic reflection structure 19 has better structural stability. Further, since the plurality of through holes 18-1 are distributed outside the overlapping region, electrical isolation of a non-resonant region is achieved, and the generation of a piezoelectric effect in the non-resonant region is reduced, thereby reducing the influence of a pseudo-mode on a target mode.

In some embodiments, the material of the first support column 20 can be the same as or different from that of the upper conductive layer 17, which is not specifically limited in the present disclosure. When the first support column 20 and the upper conductive layer 17 are both made of a metal material, the first support column 20 and the upper conductive layer 17 can be obtained by etching the same metal layer.

In some embodiments, a second cavity 11 is disposed between the substrate 10 and the lower conductive layer 12, and longitudinal acoustic waves can be reflected by the second cavity 11, thereby reducing energy leakage.

A positional relationship between the plurality of through-holes 18-1 of the first cavity 18 and the second cavity 11 is as follows: orthographic projections of a part of through holes close to the center of the overlapping region among the plurality of through holes 18-1 in the stacking direction are located in the second cavity 11, for embodiment in FIG. 1, an orthographic projection of a through hole 18-1 on a leftmost end among the plurality of through holes 18-1 in the stacking direction is located in the second cavity 11, and orthographic projections of a part of through holes away from the center of the overlapping region among the plurality of through holes 18-1 in the stacking direction do not overlap with an orthographic projection of the second cavity 11 in the stacking direction, for embodiment in FIG. 1, orthographic projections of three through holes on a rightmost end among the plurality of through holes 18-1 do not overlap with the orthographic projection of the second cavity 11 in the stacking direction; or, the orthographic projections of a part of through holes close to the center of the overlapping region among the plurality of through holes 18-1 in the stacking direction are located in the second cavity 11, so as to improve the performance of the resonator.

In some embodiments, referring to FIG. 2, the spacing between two adjacent first support columns 20 is a first spacing, and among a plurality of first spacings, the number of different first spacings is greater than or equal to two, so that the first acoustic reflection structure 19 can match acoustic waves of two or more wavelengths, that is, the first acoustic reflection structure 19 can reflect acoustic waves of a plurality of different wavelengths.

In some embodiments, the spacing between two adjacent first support columns 20 is a first spacing, and among the plurality of first spacings, the number of identical first spacings is greater than or equal to two, so that the first acoustic reflection structure 19 can reflect lateral acoustic waves of the same wavelength for two or more times. By adjusting the first spacing, the first acoustic reflection structure 19 can perform targeted reflection according to the wavelengths of the laterally leaked acoustic waves, thereby improving the reflection effect.

In some embodiments, as shown in FIG. 2, the upper conductive layer 17 is provided with an anchoring portion 17-1, the anchoring portion 17-1 is located above the first cavity 18, and the surface of the side of the anchoring portion 17-1 that faces away from the piezoelectric layer 13 is an undulating surface. In this way, a top face of the anchoring portion 17-1 can also cooperate with the air outside the upper conductive layer 17 by undulating changes to form an impedance mismatch, so as to reflect lateral acoustic waves leaked from a higher position, thereby further suppressing energy leakage.

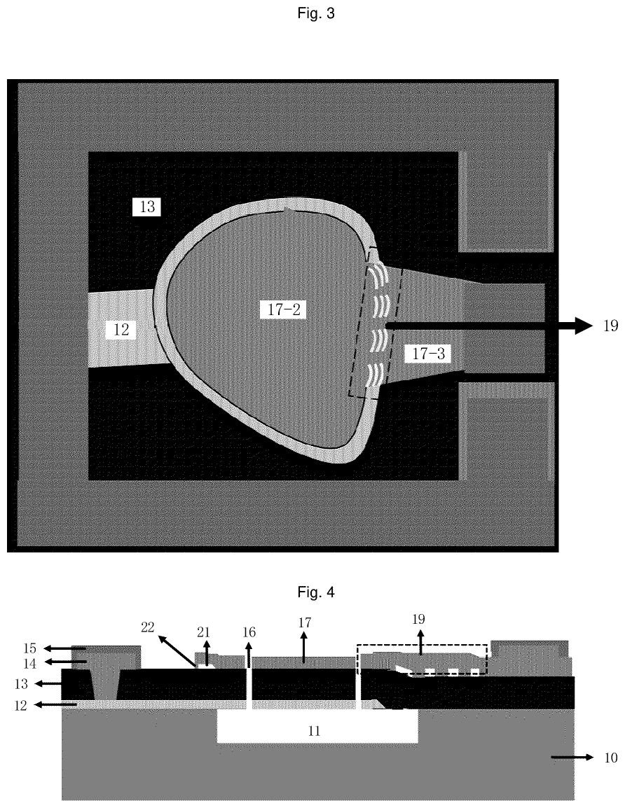

In some embodiments, as shown in FIG. 3, a plurality of first cavities 18 are disposed outside the overlapping region, and the plurality of first cavities 18 are distributed at intervals along the periphery of the overlapping region. In this way, by a plurality of first acoustic reflection structures 19 formed by the plurality of first cavities 18, a continuous acoustic reflection structure can be formed at a plurality of positions on the boundary of the overlapping region.

In some embodiments, as shown in FIG. 3, among the plurality of first cavities 18, the number of through holes contained in at least two first cavities 18 is different, so that targeted settings can be performed according to different degrees of acoustic wave leakage at different positions.

In some embodiments, as shown in FIG. 3, among the plurality of first cavities 18, the number of through holes contained in at least two first cavities 18 is also be the same.

In some embodiments, as shown in FIG. 3, the upper conductive layer 17 includes an upper electrode 17-2 located inside the overlapping region, and an upper electrode lead-out portion 17-3 located outside the overlapping region, the periphery of the upper electrode 17-2 is composed of a first edge and a second edge, and the upper electrode 17-2 is connected with the upper electrode lead-out portion 17-3 by the first edge. On this basis, the first cavity 18 is located on the first edge. A connection portion of the upper electrode 17-2 and the upper electrode lead-out portion 17-3 form the foregoing anchoring portion 17-1.

It should be aware that, in the above various possible implementations described with respect to the first acoustic reflection structure 19 in Embodiment 1, any combination and change can be performed according to actual requirements on the premise of generating no conflict or contradiction, and embodiments obtained by combinations and changes still belong to the scope recorded in the present disclosure.

### Embodiment 2

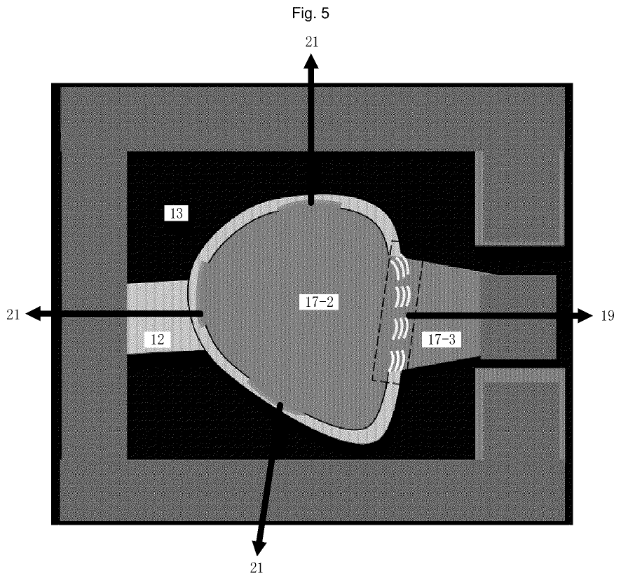

Referring to FIG. 4, the acoustic reflection structure includes a second acoustic reflection structure, and the second acoustic reflection structure is located on the second edge of the upper electrode 17-2. Specifically, the second acoustic reflection structure is that: a third cavity 21 is disposed between the upper electrode 17-2 and the piezoelectric layer 13, and the third cavity 21 is located on the second edge of the upper electrode 17-2.

In this way, through an impedance mismatch formed by the third cavity 21 and the upper electrode 17-2, the second acoustic reflection structure can reflect the lateral acoustic waves, thereby improving the quality factor.

In some embodiments, referring to FIG. 4, the side of the third cavity 21 that faces away from the center of the overlapping region is closed by a second support column 22 supported between the upper electrode 17-2 and the piezoelectric layer 13. Therefore, the second acoustic reflection structure can conveniently form a double-end closed structure, that is, both the left side and the right side of the third cavity 21 are closed in FIG. 4. Accordingly, the quality factor can be effectively improved, and the heat dissipation of the upper electrode 17-2 on the second edge can also be ensured.

In some embodiments, referring to FIG. 5, a plurality of third cavities 21 are disposed between the upper electrode 17-2 and the piezoelectric layer 13, and the plurality of third cavities 21 are distributed at intervals along the second edge. Therefore, the plurality of third cavities 21 can conveniently reflect the laterally leaked acoustic waves at different positions of the second edge.

In some embodiments, as shown in FIG. 4, the second cavity 11 is disposed between the substrate 10 and the lower conductive layer 12, and the longitudinal acoustic waves can be reflected by the second cavity 11, thereby reducing energy leakage.

In some embodiments, referring to FIG. 4, when the second cavity 11 is disposed between the substrate 10 and the lower conductive layer 12, an orthographic projection of the third cavity 21 in the stacking direction does not overlap with the orthographic projection of the second cavity 11 in the stacking direction.

### Embodiment 3

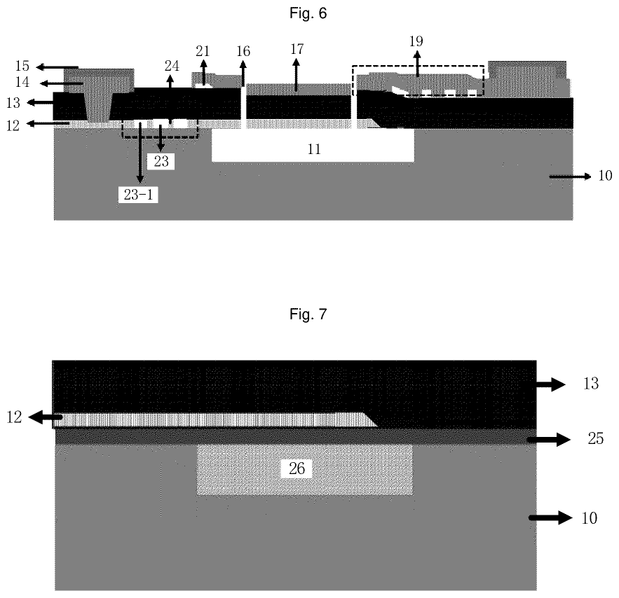

Referring to FIG. 6, the acoustic reflection structure includes a third acoustic reflection structure, and the third acoustic reflection structure is located outside the overlapping region. Specifically, the third acoustic reflection structure is that: a fourth cavity 23 located outside the overlapping region is disposed inside the lower conductive layer 12, the fourth cavity 23 penetrates through the lower conductive layer 12, a plurality of third support columns 24 supported between the piezoelectric layer 13 and the substrate 10 are disposed inside the fourth cavity 24, the plurality of third support columns 24 divide the fourth cavity 23 into a plurality of compartments 23-1, and the plurality of compartments 23-1 are distributed in the direction from a center of the overlapping region to a boundary of the overlapping region.

In this way, by an impedance mismatch formed by the plurality of compartments 23-1 with the third support columns 24 and the lower conductive layer 12, the third acoustic reflection structure has a continuous acoustic reflection capability. The third acoustic reflection structure can reflect the lateral acoustic waves for multiple times, thereby improving the quality factor.

Since the third support column 24 is supported between the piezoelectric layer 13 and the lower conductive layer 12, the heat dissipation capability of the resonator can be enhanced By the plurality of compartments 23-1. In addition, By the third support column 24, the piezoelectric layer 13 can be better supported, and the third acoustic reflection structure has better structural stability. Since the plurality of compartments 23-1 are located outside the overlapping region, electrical isolation of the non-resonant region can be achieved, and the generation of the piezoelectric effect in the non-resonant region can be reduced, thereby reducing the influence of the pseudo-mode on the target mode.

In some embodiments, as shown in FIG. 6, the second cavity 11 is disposed between the substrate 10 and the lower conductive layer 12, and the longitudinal acoustic waves can be reflected by the second cavity 11, thereby reducing energy leakage.

In some embodiments, referring to FIG. 6, when the second cavity 11 is disposed between the substrate 10 and the lower conductive layer 12, an orthographic projection of the fourth cavity 23 in the stacking direction does not overlap with the orthographic projection of the second cavity 11 in the stacking direction.

In some embodiments, the spacing between two adjacent third support columns 24 is a second spacing, and among a plurality of second spacings, the number of different second spacings is greater than or equal to two, so that the third acoustic reflection structure can match acoustic waves of two or more wavelengths, that is, the third acoustic reflection structure can reflect acoustic waves of a plurality of different wavelengths.

In some embodiments, the spacing between two adjacent third support columns 24 is the second spacing, and among the plurality of second spacings, the number of identical second spacings is greater than or equal to two, so that the third acoustic reflection structure can reflect lateral acoustic waves of the same wavelength for two or more times. By adjusting the second spacing, the third acoustic reflection structure can perform targeted reflection according to the wavelengths of the laterally leaked acoustic waves, thereby improving the reflection effect.

In different embodiments, the above Embodiments 1 to 3 can be flexibly combined according to requirements, for embodiment, as shown in FIG. 4, the first acoustic reflection structure 19 and the second acoustic reflection structure are simultaneously present in the bulk acoustic wave resonator, the first acoustic reflection structure 19 is located on the first edge, and the second acoustic reflection structure is located on the second edge; and as another embodiment, as shown in FIG. 6, the first acoustic reflection structure 19, the second acoustic reflection structure and the third acoustic reflection structure are simultaneously present in the bulk acoustic wave resonator.

Optionally, the second cavity 11, the third cavity 21 and the fourth cavity 23 are distributed in the direction from a center of the overlapping region to a boundary of the overlapping region.

Another aspect of the embodiments of the present disclosure provides a bulk acoustic wave resonator manufacturing method, and the method includes:

Step 01: forming a lower conductive layer 12 and a piezoelectric layer 13 on a substrate 10.

As shown in FIG. 7, the lower conductive layer 12 and the piezoelectric layer 13 are formed on the substrate 10. In order to further improve the quality of the lower conductive layer 12, before the lower conductive layer 12 is formed, a seed layer 25 is deposited on the substrate 10 at first, and then the lower conductive layer 12 is fabricated on the seed layer 25.

Step 02: forming, on the piezoelectric layer 13, a plurality of first sacrificial portions 27, an upper conductive layer 17 covering the plurality of first sacrificial portions 27, and first support columns 20 filled between two adjacent first sacrificial portions 27, wherein the lower conductive layer 12, the piezoelectric layer 13 and the upper conductive layer 17 have an overlapping region in a stacking direction, the plurality of first sacrificial portions 27 are located outside the overlapping region, and the plurality of first sacrificial portions 27 are distributed at intervals in a direction from a center of the overlapping region to a boundary of the overlapping region.

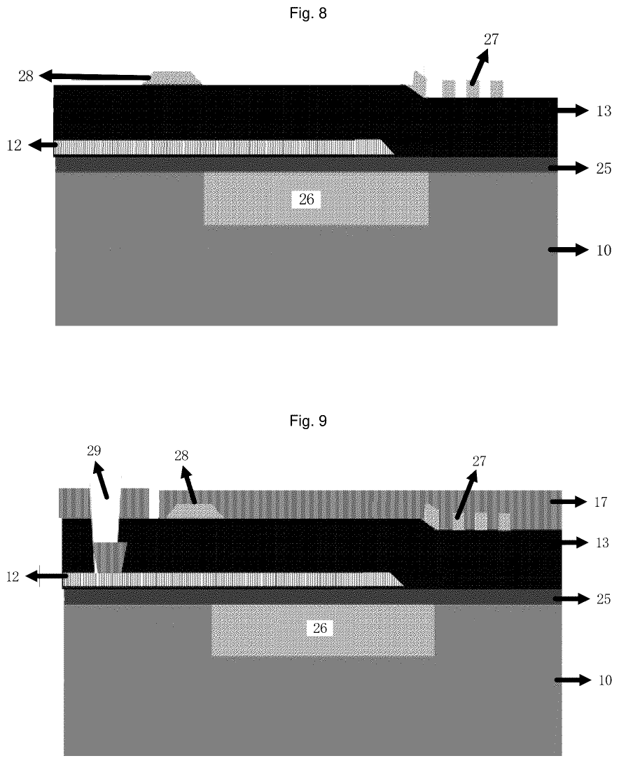

As shown in FIG. 8, the plurality of first sacrificial portions 27 are formed on the piezoelectric layer 13 at first, the plurality of first sacrificial portions 27 are located outside the overlapping region, and the plurality of first sacrificial portions 27 are distributed at intervals in the direction from a center of the overlapping region to a boundary of the overlapping region.

As shown in FIG. 9, the piezoelectric layer 13 is etched to form a lower conductive layer lead-out hole 29. Then, the upper conductive layer 17 and the plurality of first support columns 20 are fabricated, the upper conductive layer 17 covers the plurality of first sacrificial portions 27, and the plurality of first support columns 20 are filled between every two adjacent first sacrificial portions 27. When the first support column 20 and the upper conductive layer 17 are both made of a metal material, the first support column 20 and the upper conductive layer 17 are obtained by etching the same metal layer.

Step 03: releasing the plurality of first sacrificial portions 27 to form a first cavity 18 between the upper conductive layer 17 and the piezoelectric layer 13, wherein the interior of the first cavity 18 is divided by the plurality of first support columns 20 into a plurality of through holes which are distributed in the direction from a center of the overlapping region to a boundary of the overlapping region.

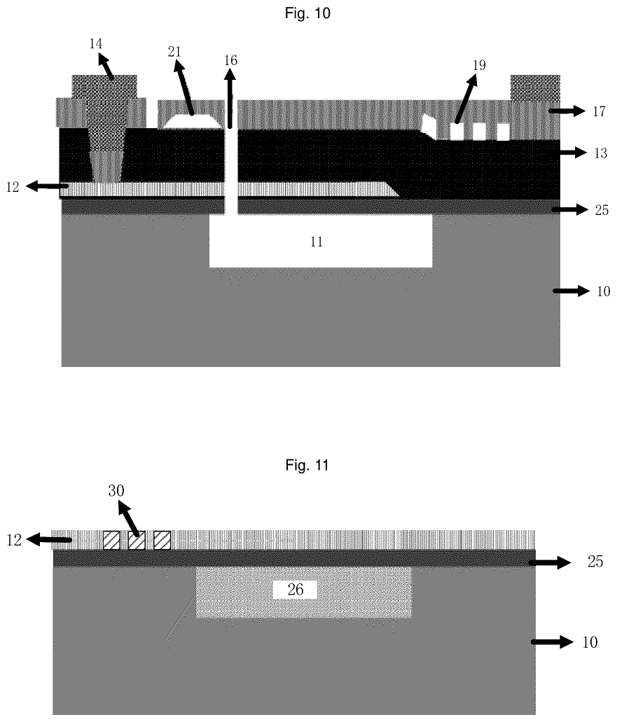

As shown in FIG. 10, the plurality of first sacrificial portions 27 are released to form the first cavity 18 between the upper conductive layer 17 and the piezoelectric layer 13, and the first cavity 18 is divided by the plurality of first support columns 20 into the plurality of through holes which are distributed in the direction from a center of the overlapping region to a boundary of the overlapping region.

Optionally, when the lower conductive layer 12 and the piezoelectric layer 13 are formed on the substrate 10, as shown in 7, the substrate 10 can be etched first to form a second cavity 11, and then the second cavity 11 is filled with a fourth sacrificial portion 26, so that an upper surface of the substrate 10 is flush. Then, the seed layer 25, the lower conductive layer 12 and the piezoelectric layer 13 are sequentially fabricated. Finally, as shown in FIG. 1, FIG. 4, FIG. 6 or FIG. 10, by etching the upper conductive layer 17, the piezoelectric layer 13, the lower conductive layer 12 and the seed layer 25, a release hole 16 communicating to the fourth sacrificial portion 26 is formed, so as to release the fourth sacrificial portion 26 via the release hole 16, wherein the release hole 16 is located on the edge of a third cavity 21.

Optionally, before the step S03, as shown in FIG. 1, FIG. 4, FIG. 6 or FIG. 10, a metal is also deposited to form an electrode connection end 14. As shown in FIG. 1, FIG. 4 or FIG. 6, an electrode connection portion 15 is further disposed on the electrode connection end 14.

Optionally, as shown in FIG. 8 to FIG. 10, forming, on the piezoelectric layer 13, the plurality of first sacrificial portions 27, the upper conductive layer 17 covering the plurality of first sacrificial portions 27, and the plurality of first support columns 20 filled between two adjacent first sacrificial portions 27, includes:
forming a first sacrificial layer on the piezoelectric layer 13, and then, etching the first sacrificial layer to form the plurality of first sacrificial portions 27 and a second sacrificial portion 28 as shown in FIG. 8, wherein the plurality of first sacrificial portions 27 are located on the first edge, and the second sacrificial portion 28 is located on the second edge; and
forming, on the piezoelectric layer 13, the upper conductive layer 17 covering the plurality of first sacrificial portions 27 and the second sacrificial portion 28, and the plurality of first support columns 20 filled between two adjacent first sacrificial portions 27.

Subsequently, the first sacrificial portions 27 are released to form the first cavity 18, and the second sacrificial portion 28 is released to form the third cavity 21 located on the second edge.

Optionally, as shown in FIG. 11 to FIG. 13, forming the lower conductive layer 12 and the piezoelectric layer 13 on the substrate 10 includes:

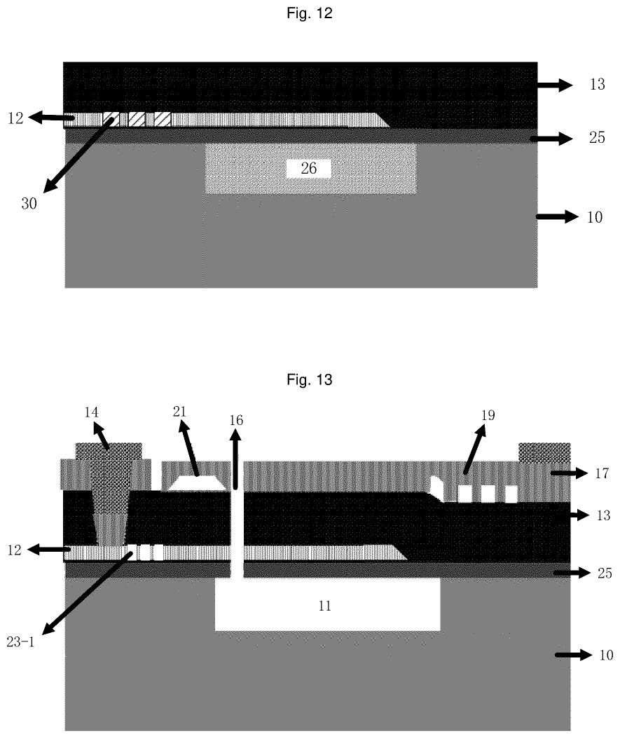

As shown in FIG. 11, firstly forming the lower conductive layer 12 on the substrate 10; then, etching the lower conductive layer 12 to form a fourth cavity 23 penetrating through the lower conductive layer 12 in the lower conductive layer 12, and a plurality of third support columns 24 located inside the fourth cavity 23, wherein the plurality of third support columns 24 divide the fourth cavity 23 into a plurality of compartments 23-1, and the plurality of compartments 23-1 are distributed in the direction from a center of the overlapping region to a boundary of the overlapping region; respectively filling the plurality of compartments 23-1 with third sacrificial portions 30, so that the surface of the side of the lower conductive layer 12 that faces away from the substrate 10 is flush; and as shown in FIG. 12, forming the piezoelectric layer 13 on the surface of the side of the lower conductive layer 12 that faces away from the substrate 10. Next, the upper conductive layer 17 can be fabricated according to the foregoing steps 02 and 03. Finally, the third sacrificial portions 30 are released, so that the compartments 23-1 are filled with air again.

The foregoing descriptions are merely preferred embodiments of the present disclosure and are not intended to limit the present disclosure, and for those skilled in the art, the present disclosure may have various changes and modifications. Any modifications, equivalent replacements, improvements, or the like, made within the spirits and principles of the present disclosure, shall fall within the protection scope of the present disclosure.

What is claimed is:

1. A bulk acoustic wave resonator, comprising a substrate, and a lower conductive layer, a piezoelectric layer and an upper conductive layer, which are sequentially disposed on the substrate in a stacked manner, wherein the lower conductive layer, the piezoelectric layer and the upper conductive layer have an overlapping region in a stacking direction, a first cavity located between the upper conductive layer and the piezoelectric layer is disposed outside the overlapping region, a plurality of first support columns are disposed in the first cavity, the plurality of first support columns are supported between the piezoelectric layer and the upper conductive layer, the plurality of first support columns divide the first cavity into a plurality of through holes, and the plurality of through holes are distributed in a direction from a center of the overlapping region to a boundary of the overlapping region.

2. The bulk acoustic wave resonator according to claim 1, wherein a second cavity is disposed between the substrate and the lower conductive layer; and
orthographic projections of a part of through holes close to the center of the overlapping region among the plurality of through holes in the stacking direction are located in the second cavity; and/or, orthographic projections of a part of through holes away from the center of the overlapping region among the plurality of through holes in the stacking direction do not overlap with an orthographic projection of the second cavity in the stacking direction.

3. The bulk acoustic wave resonator according to claim 1, wherein a spacing between two adjacent first support columns is a first spacing, and at least part of the first spacings are different from each other.

4. The bulk acoustic wave resonator according to claim 1, wherein a plurality of the first cavities are disposed outside the overlapping region, and the plurality of the first cavities are distributed at intervals along a periphery of the overlapping region.

5. The bulk acoustic wave resonator according to claim 4, wherein among the plurality of first cavities, a number of through holes contained in at least two first cavities is different.

6. The bulk acoustic wave resonator according to claim 1, wherein the upper conductive layer is provided with an anchoring portion, the anchoring portion is located above the first cavity, and a surface of a side of the anchoring portion that faces away from the piezoelectric layer is an undulating surface.

7. The bulk acoustic wave resonator according to claim 1, wherein the upper conductive layer comprises an upper electrode located in the overlapping region, and an upper electrode lead-out portion located outside the overlapping region, a periphery of the upper electrode is composed of a first edge and a second edge, the upper electrode is connected with the upper electrode lead-out portion by the first edge, a third cavity is disposed between the upper electrode and the piezoelectric layer, the third cavity is located on the second edge, and the first cavity is located on the first edge.

8. The bulk acoustic wave resonator according to claim 7, wherein a side of the third cavity that faces away from the center of the overlapping region is closed by a second support column supported between the upper electrode and the piezoelectric layer.

9. The bulk acoustic wave resonator according to claim 7, wherein a plurality of third cavities are disposed between the upper electrode and the piezoelectric layer, and the plurality of third cavities are distributed at intervals along the second edge.

10. The bulk acoustic wave resonator according to claim 7, wherein when the second cavity is disposed between the substrate and the lower conductive layer, an orthographic projection of the third cavity in the stacking direction does not overlap with an orthographic projection of the second cavity in the stacking direction.

11. The bulk acoustic wave resonator according to claim 7, wherein a fourth cavity located outside the overlapping region is disposed in the lower conductive layer, the fourth cavity penetrates through the lower conductive layer, a plurality of third support columns supported between the piezoelectric layer and the substrate are disposed in the fourth cavity, the plurality of third support columns divide the fourth cavity into a plurality of compartments, and the plurality of compartments are distributed in the direction from the center of the overlapping region to the boundary of the overlapping region.

12. The bulk acoustic wave resonator according to claim 11, wherein when the second cavity is disposed between the substrate and the lower conductive layer, an orthographic projection of the fourth cavity in the stacking direction does not overlap with an orthographic projection of the second cavity in the stacking direction.

13. The bulk acoustic wave resonator according to claim 12, wherein the second cavity, the third cavity and the fourth cavity are distributed in the direction from the center of the overlapping region to the boundary of the overlapping region.

14. The bulk acoustic wave resonator according to claim 11, wherein a spacing between two adjacent third support columns is a second spacing, and at least part of the second spacings are different from each other.

15. A bulk acoustic wave resonator manufacturing method, comprising:
forming a lower conductive layer and a piezoelectric layer on a substrate;
forming, on the piezoelectric layer, a plurality of first sacrificial portions, an upper conductive layer covering the plurality of first sacrificial portions, and first support columns filled between two adjacent first sacrificial portions, wherein the lower conductive layer, the piezoelectric layer and the upper conductive layer have an overlapping region in a stacking direction, the plurality of first sacrificial portions are located outside the overlapping region, and the plurality of first sacrificial portions are distributed at intervals in a direction from a center of the overlapping region to a boundary of the overlapping region; and
releasing the plurality of first sacrificial portions to form a first cavity between the upper conductive layer and the piezoelectric layer, wherein the first cavity is divided by the plurality of first support columns into a plurality of through holes which are distributed in the direction from the center of the overlapping region to the boundary of the overlapping region.

16. The bulk acoustic wave resonator manufacturing method according to claim 15, wherein forming, on the piezoelectric layer, the plurality of first sacrificial portions, the upper conductive layer covering the plurality of first sacrificial portions, and the plurality of first support columns filled between two adjacent first sacrificial portions, comprises:
forming a first sacrificial layer on the piezoelectric layer;
etching the first sacrificial layer to form the plurality of first sacrificial portions and a second sacrificial portion; and
forming, on the piezoelectric layer, the upper conductive layer covering the plurality of first sacrificial portions and the second sacrificial portion, and the plurality of first support columns filled between two adjacent first sacrificial portions, wherein the second sacrificial portion is released to form a third cavity located between the upper conductive layer and the piezoelectric layer, the upper conductive layer comprises an upper electrode located in the overlapping region, and an upper electrode lead-out portion located outside the overlapping region, a periphery of the upper electrode is composed of a first edge and a second edge, the upper electrode is connected with the upper electrode lead-out portion by the first edge, a third cavity is located on the second edge, and the first cavity is located on the first edge.

17. The bulk acoustic wave resonator manufacturing method according to claim 15, wherein forming the lower conductive layer and the piezoelectric layer on the substrate comprises:
forming the lower conductive layer on the substrate;
etching the lower conductive layer to form a fourth cavity penetrating through the lower conductive layer in the lower conductive layer, and a plurality of third support columns located in the fourth cavity, wherein the plurality of third support columns divide the fourth cavity into a plurality of compartments, and the plurality of compartments are distributed in the direction from the center of the overlapping region to the boundary of the overlapping region;
respectively filling the plurality of compartments with third sacrificial portions, so that a surface of a side of the lower conductive layer that faces away from the substrate is flush; and
forming the piezoelectric layer on a surface of a side of the lower conductive layer that faces away from the substrate.

18. The bulk acoustic wave resonator manufacturing method according to claim 17, wherein forming the lower conductive layer on the substrate comprises: depositing a seed layer on the substrate, and forming the lower conductive layer on the seed layer.

19. The bulk acoustic wave resonator manufacturing method according to claim 16, wherein before forming the lower conductive layer on the substrate, the method further comprises:
etching the substrate to form a second cavity; and
filling the second cavity with a fourth sacrificial portion, so that an upper surface of the substrate is flush.

20. The bulk acoustic wave resonator manufacturing method according to claim 19, wherein the method further comprises:
at least etching the upper conductive layer, the piezoelectric layer and the lower conductive layer to form a release hole connected to the fourth sacrificial portion, so as to release the fourth sacrificial portion via the release hole, wherein the release hole is located on an edge of the third cavity.
